(19) United States
(12) Patent Application Publication
(10) Pub. No.: US 2006/0266953 A1
(43) Pub. Date: Nov. 30, 2006

(54) Method and system for determining a positioning error of an electron beam of a scanning electron microscope

(76) Inventors: Uwe Kramer, Dresden (DE); Christoph Nacke, Dresden (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/138,673

(22) Filed: May 27, 2005

(51) Int. Cl. H01J 37/28

(52) U.S. Cl. 250/491.1; 250/310; 250/307

(57) ABSTRACT

A substrate having at least four reference patterns at respective nominal positions on a surface is provided. Using a scanning electron microscope and positioning the wafer stage at respective nominal positions of each reference pattern, each reference pattern is scanned. After determining at least a first and a second intensity profile for each pattern, a reference position offset from each nominal position is calculated. The reference position offsets are used to determine a positioning error of the scanning electron microscope.

### FIELD OF THE INVENTION

The present invention relates to inspecting finely structured DRAM cells with a scanning electron microscope, and more particularly, to a method for determining a positioning error of an electron beam of a scanning electron microscope by measuring at least four reference patterns and determining the positioning error by an simulation model.

### BACKGROUND

The manufacturing of integrated circuits includes repeatedly projecting a pattern in a lithographic step onto a semiconductor wafer and processing the wafer to transfer the pattern into a layer deposited on the wafer surface or into the substrate of the wafer. This processing includes depositing a resist film layer on the surface of the semiconductor substrate, projecting the pattern onto the resist film layer, and developing or etching the resist film layer to create a resist structure. The resist structure is transferred into a layer deposited on the wafer surface or into the substrate in an etching step. Planarization and other intermediate processes may be necessary to prepare a projection of a successive mask level.

The pattern being projected is provided on a photo mask. The photo mask is illuminated by a light source having a wavelength which is selected in a range from visible light to deep-UV in modern applications. The part of the light which is not blocked or attenuated by the photo mask is projected onto the resist film layer on the surface of the semiconductor wafer.

In order to manufacture patterns having line widths in the range of 70 nm or smaller, large efforts have to be undertaken to guarantee sufficient dimensional accuracy of patterns projected onto the resist film layer. The dimensional accuracy of patterns depends on many factors, e.g., the illumination condition of the exposure tool, the characteristics of the resist film layer with respect to exposure dose in different regions on the wafer and under varying illumination conditions. Control of dimensional accuracy is performed by measuring the size of portions of a test pattern of the current layer with an inspection tool. Typically, CD-SEM structures are used to quantify the amount of deviation from the design value, e.g., by using a scanning electron microscope or SEM-tool.

As an alternative or in addition, patterns representing a certain layer of the integrated circuit can be inspected by the SEM-tool as well so as to control dimensional accuracy.

However, measuring the accuracy of critical dimensions directly is connected with a few drawbacks. Usually a scanning window defines the surface area of the circuit to be inspected. A critical parameter is the accuracy of selecting this scanning window, which has in turn an influence on the accuracy of the measurement of the layer of an integrated circuit.

However, with decreasing feature sizes of patterns the precise determination of positional accuracy gets even more important. With the advent of light sources having a shorter wavelength, i.e., 248 nm, 193 nm, or 157 nm as used nowadays, the dimensions of the structures on the semiconductor are in the same order of magnitude as the matching in the positioning of the scanning window defined by the SEM-tool. Systematic and non-systematic positioning errors, like shifts, rotation perpendicularity or magnification, become more and more important. Failing to control those parameters would ultimately result in a corrupted measurement during inspection and thus to a low yield of the produced circuits.

A method and system for determining a positioning error of an electron beam of a scanning electron microscope, which contributes to a measurement recipe of a scanning electron microscope during inspection of integrated circuits, are desirable.

### SUMMARY

A method for determining a positioning error of an electron beam of a scanning electron microscope includes providing a substrate having at least four reference patterns at respective nominal positions on a surface of the substrate, providing a scanning electron microscope, positioning the wafer stage at respective nominal positions of each reference pattern, scanning each reference pattern using an electron beam emitted from the electron source, using the detector to determine an intensity distribution of scattered electrons within a scanning window of the electron source, determining at least a first intensity profile and a second intensity profile for each pattern, calculating a reference position offset from each nominal position for each reference pattern using at least the first intensity profile and the second intensity profile, and determining a positioning error of the scanning electron microscope using the reference position offsets of each reference pattern. Each reference pattern has a continuously increasing first dimension along a first axis and a continuously increasing second dimension along a second axis. The first axis is different from the second axis. The scanning electron microscope includes a wafer stage, an electron source, and a detector. The first intensity profile is measured along a first direction and the second intensity profile is measured along a second direction.

Reference patterns are measured by the scanning electron microscope. The measurements are performed using the scanning electron microscope with an electron source and a wafer stage to align the substrate. The alignment is usually connected with a positioning error. This yields to different positioning of scanning windows for different measurements and to different matching in the positioning of scanning windows for different measurements, which would make the measurements imprecise. According to the present invention, a reference position offset is calculated as a variation of the measured continuously increasing first and second dimension. When comparing the actual measured first profile and second intensity profiles to the known geometry of the reference patterns, the reference position offset is calculated. This determines the size and the direction of the positioning error of the scanning electron microscope, which can be attributed in further measurements.

Some or all of the following aspects may be included in the above method. Providing a substrate includes providing a substrate with a circuit pattern arranged within a rectangular frame and with each reference pattern arranged in a respective corner of the rectangular frame. The reference patterns are arranged in a respective corner of the rectangular frame, which allows for a relatively accurate determination of the positioning error. Alternatively, providing a substrate includes that each reference pattern is arranged symmetrically with respect to the first axis and with respect to the second axis or that the first axis and the second axis are substantially perpendicular to each other.

Determining at least the first intensity profile and the second intensity profile for each of the patterns includes selecting the first direction substantially parallel to the first axis at a first distance, and selecting the second direction substantially parallel to the second axis at a second distance. Alternatively, determining at least the first intensity profile and the second intensity profile for each pattern includes determining at least a third intensity profile and a fourth intensity profile for each pattern. The third intensity profile is measured along a third direction and the fourth intensity profile is measured along a fourth direction.

Determining at least a third intensity profile and a fourth intensity profile for each pattern further includes selecting the third direction substantially parallel to the first axis at a third distance and at an opposite side with respect to the first direction, and selecting the fourth direction substantially parallel to the second axis at a fourth distance and at an opposite side with respect to the second direction.

Calculating a reference position for each reference pattern includes determining error vectors for each reference position. The error vector is calculated from the difference of the respective nominal position to the first distance, the second distance, the third distance, and the fourth distance.

The above method may include some or all of the following: providing a simulation model of the scanning electron microscope, and determining the parameters form the error vectors for each of the reference positions. The simulation model has parameters capable of describing positioning errors induced by beam shifts, beam rotation, perpendicularity of the beam, and magnification errors;

Providing the substrate further includes providing a plurality of structural elements. The structural elements have a minimal size and represent a layer of an integrated circuit.

Aligning the wafer stage and positioning the scanning window at respective nominal positions is performed using an optical microscope with an accuracy relatively larger than the minimal size of the structural elements. Alternatively, aligning the wafer stage and positioning the scanning window at respective nominal positions is performed using the scanning electron microscope with an accuracy relatively larger than the minimal size of the structural elements.

The above method may include some or all of the following: providing a measurement recipe for the scanning electron microscope to measure features of the structural elements, modifying the recipe taking into account the positioning errors described by the simulation model, and measuring the features of the structural elements.

The respective nominal positions are derived from a layout tool. The layout provides data for producing the substrate having the pattern. The respective nominal positions are derived from reference wafer and a reference scanning electron microscope.

A system for measuring patterns with a scanning electron microscope includes a substrate having at least four reference patterns at respective nominal positions on a surface of the substrate, a scanning electron microscope, means for positioning the wafer stage at respective nominal positions of each reference pattern, means for scanning each reference pattern using an electron beam emitted from the electron source and using the detector to determine an intensity distribution of scattered electrons within a scanning window of the electron source, means for determining at least a first intensity profile and a second intensity profile for each pattern, means for calculating a reference position offset from each nominal position for each reference pattern using at least the first intensity profile and the second intensity profile, and means for determining a positioning error of the scanning electron microscope using the reference position offsets of each reference pattern. Each reference pattern has a continuously increasing first dimension along a first axis and a continuously increasing second dimension along a second axis. The first axis is different from the second axis. The scanning electron microscope includes a wafer stage, an electron source, and a detector. The first intensity profile is measured along a first direction and the second intensity profile is measured along a second direction.

### BRIEF DESCRIPTION OF THE DRAWINGS

The above features of the present invention will be more clearly understood from consideration of the following descriptions in connection with accompanying drawings in which:

FIG. 1 diagrammatically illustrates a scanning electron microscope in a side view according to an embodiment of the invention;

FIG. 2 diagrammatically illustrates a semiconductor wafer in a top view according to an embodiment of the invention

FIGS. 3A to 3C diagrammatically illustrate reference patterns according to an embodiment of the invention;

FIG. 4 diagrammatically illustrate a further reference pattern when applying the method steps according to an embodiment of the invention;

FIG. 5 diagrammatically illustrate intensity distributions when applying the method steps according to an embodiment of the invention; and

FIG. 6 diagrammatically illustrate a further reference pattern when applying the method steps according to another embodiment of the invention.

### DETAILED DESCRIPTION

Embodiments of the method are described with respect to inspecting and measuring of a layer of an integrated circuit. The invention, however, is also useful for other substrates, e.g., liquid crystal panels.

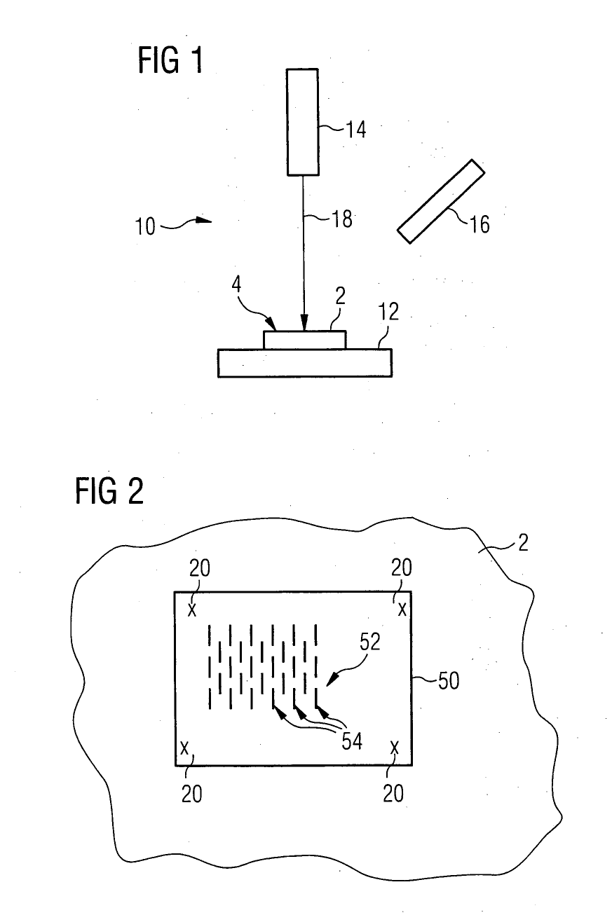

With respect to FIG. 1, a scanning electron microscope 10 is shown in a side view. FIG. 1 is an illustration, i.e., the individual components shown in FIG. 1 are neither describe the full functionality of a scanning electron microscope 10 nor are the elements shown true scale.

The scanning electron microscope 10 includes a wafer stage 12, an electron source 14, and a detector 16. The wafer stage 12 carries a semiconductor wafer or substrate 2. In modern technologies, the substrate 2 has, for example, a diameter of 300 mm or more. The electron source 14 is disposed opposite the substrate 2 and faces in the direction of the substrate 20.

When emitting an electron beam 18 onto the surface of the substrate 2, electrons of the electron beam 18 are scattered. Part of the scattered electrons are detected by the detector 16. The detector 16 includes, for example, a multi channel diode-array, a photomultiplier, or other type of instrument capable of detecting electrons.

When performing a measurement, the wafer stage 12 is aligned such that the electron beam scans the region of interest. Usually, the scanning window has a width and a length of approximately 10 μm, depending on the level of magnification provided by the scanning electron microscope 10.

Referring now to FIG. 2, a small section of the surface 4 of the substrate 2 is shown. The substrate 2 includes at least four reference patterns 20 at respective nominal positions on the surface 4 of the substrate 2. The substrate further includes a circuit pattern 52 arranged within a rectangular frame 50 surrounding the circuit pattern 52. The rectangular frame 50 is disposed on a small fraction of the surface 4 of substrate 2. The circuit pattern includes a plurality of structural elements 54 having a minimal size and representing a layer of the integrated circuit. For a typical manufacturing process, the minimal size is, for example, on the order of 100 nm or less. In FIG. 2, the plurality of structural elements 54 are shown as parallel line segments, which, e.g., represent a layer for manufacturing DRAM products.

It should be noted that the rectangular frame 50 represents a single image provided by the scanning electron microscope 10. This rectangular frame 50 might be different to the actual image field used during a lithographic patterning.

Each reference pattern 20 is arranged in a respective corner of the rectangular frame 50. The reference patterns 20 have a continuously increasing first dimension 22 along a first axis 24 and a continuously increasing second dimension 26 along a second axis 28. Each reference pattern 20 is arranged symmetrically with respect to the first axis 24 and with respect to the second axis 28.

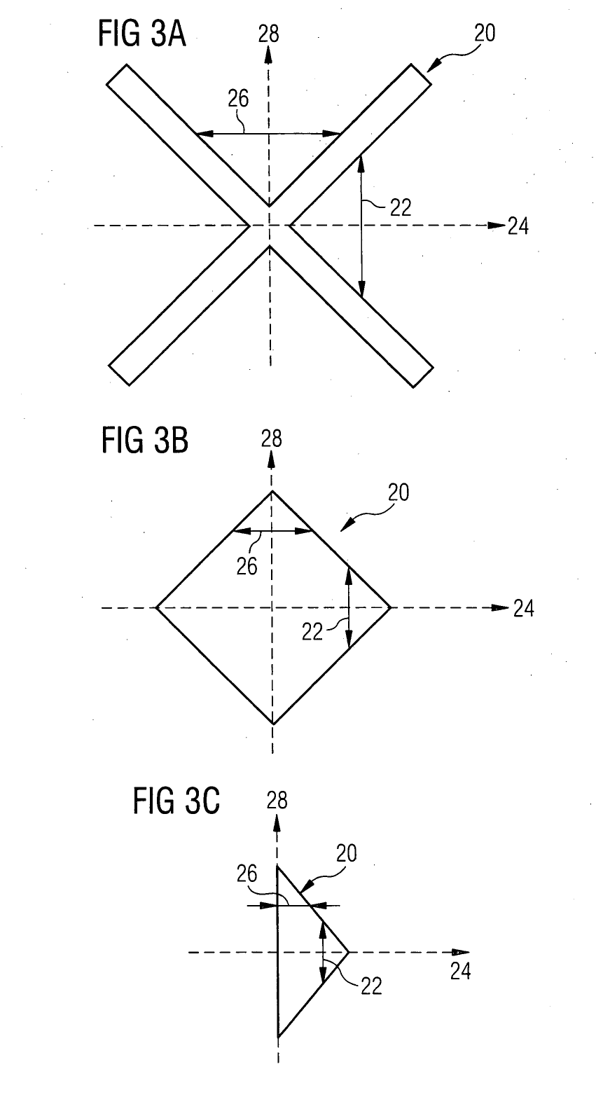

As shown in FIG. 3A, each reference pattern 20 is provided as two straight bars. The first and second bars are arranged perpendicular to each other and under an angle of 45° with respect to the first axis 24 and the second axis 28. It should be noted that other arrangements with different angles might be used as well.

The bars can be produced by photolithographic structuring of the surface 4. In this case, the continuously increasing first dimension 22 along the first axis 24 are given by a space created between adjacent bars, as indicated in FIG. 3A. The continuously increasing second dimension 26 along the second axis 28 is also by a further space created between different bars, as indicated in FIG. 3A. In this case, adjacent feature edges of the respective bars are used to define the continuously increasing first dimension 22 and/or continuously increasing second dimension 26. In another possibility (not shown in FIG. 3A), the continuously increasing first dimension 22 from the rightmost feature edge of the left bar to the rightmost feature edge of the right bar to be independent of dimensional inaccuracy of the bars. According to this procedure, a pith is measured rather then a distance and the result is independent of the actual width of the bars which might change due to process fluctuations.

The first axis 24 and the second axis 28 are, for example, substantially perpendicular to each other. The size of the reference pattern 20 is selected such that the maximum values of the continuously increasing first dimension 22 and second dimension 26 are in the range of approximately 10 μm.

In FIG. 3B, a further embodiment of the reference pattern 20 is shown. According to this embodiment, the reference pattern 20 includes a rectangular shape having its principal axis along the first axis 24 and the second axis 28. In this case, the continuously increasing first dimension 22 and second dimension 26 are defined as the width of the rectangular shaped reference pattern 20 along the first axis 24 and the second axis 28, respectively.

FIG. 3C shows a triangular shaped reference pattern 20 with one side being arranged along the second axis 28. The remaining two sides of the triangular shaped reference pattern 20 are arranged under an angle of approximately 45°, for example. In this embodiment, the continuously increasing first dimension 22 and second dimension 26 are again defined as the width of the rectangular shaped reference pattern 20 along the first axis 24 and the second axis 28, respectively

In order to inspect the structural elements 54 of circuit pattern 52, the substrate 2 is aligned with respect to the electron source 14. The aligning the wafer stage and positioning of the scanning window can be performed using an optical microscope (not shown in FIG. 1). Usually, the accuracy of this positioning is larger than the minimal size of the structural elements 54.

In another embodiment, aligning the wafer stage and positioning of the scanning window is performed using the scanning electron microscope 10 itself. This usually requires a rather low magnification, as a large part of the surface needs to be monitored. Again, the alignment error achieved during this step might be larger than the minimal size of the structural elements 54. Furthermore, the positioning of the scanning window is connected to an error, as described above.

After aligning the substrate 2 with respect to the electron source 14 by aligning the wafer stage and positioning of the scanning window, the circuit pattern 52 is inspected. Usually, a measurement recipe is provided for the scanning electron microscope 10 in order to measure features of the structural elements 54, e.g., line width or the like. The recipe describes what kind of measurement is performed and which part of the surface 4 of substrate 2 is inspected.

However, the above described inaccuracy lead to problems when inspecting a circuit pattern 52 with structural elements 54 having a line width which is similar to the spacing of the structural elements 54. As the scanning electron microscope 10 delivers signals only for surface gradients, it is not possible to distinguish the signal of the scattered electrons coming from the structural elements 54 or the space between the structural elements 54. Accordingly, the edges of the structural elements 54 or the space between the structural elements 54 might be confused during inspecting the circuit pattern 52 which might lead to wrong results.

The following describes how the positioning error associated with the electron beam 18 from electron source 14 and the wafer stage 12 is determined. In principle, each reference pattern 20 has continuously increasing dimensions along a first and a second axis and is measured by the scanning electron microscope along two directions. While many different kind of reference patterns might be used, the reference patterns 20 are symmetrical with respect to first and second axis. Four instead of two measurements are taken for each, to ease the interpretation of intensity profiles provided by detector 16. Furthermore, the following description uses Cartesian coordinates, although the invention might be performed in other system as well.

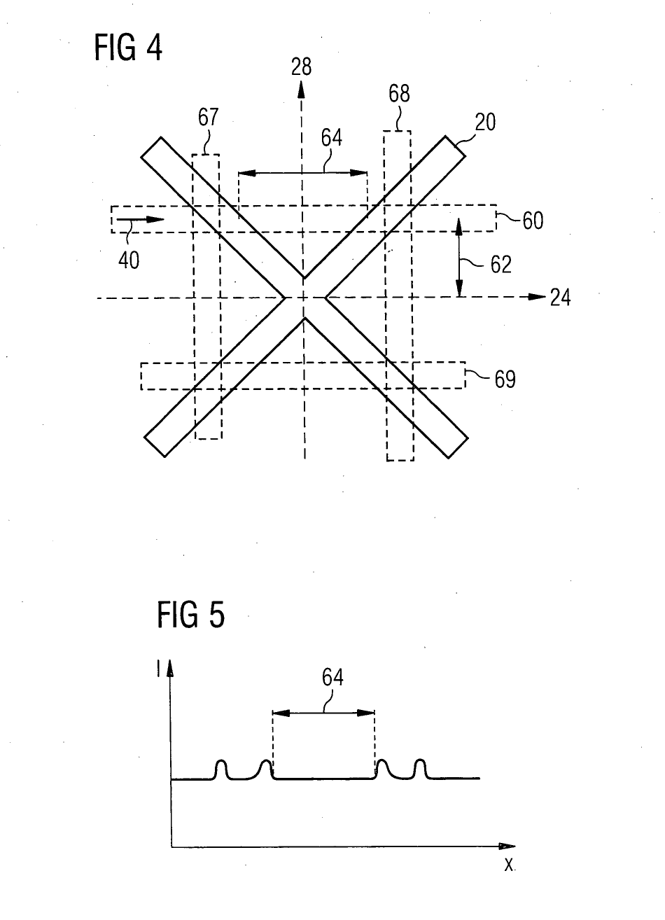

In FIG. 4, the reference pattern 20 is shown together with a first scanning window 60 along a first direction 40. The first direction is chosen parallel to the first axis 24, as shown in FIG. 4. After aligning the wafer stage 16, scanning of reference pattern 20 in the first scanning window 60 is performed at a distance 62 with respect to the nominal position of reference pattern 20. The nominal position might be given by the origin of first axis 24 and second axis 28.

Referring now to FIG. 5, a first intensity profile 32 is shown. The first intensity profile 32 represents the result of the measurement performed using detector 16. The first intensity profile 32 shows the edges of the reference pattern 20 along first direction 40. Using the distinct signature of the intensity profile 32, the actual distance 64 between the two bars of the reference pattern 20 is derived. This is transformed into a first distance 62 using simple geometric calculations.

If no positioning error has occurred, the measured first distance 62 would be identical to its nominal position. If, however, a positioning error has occurred, the measured first distance 62 is shifted by a certain amount. In principle, this value could be forwarded to the measurement recipe to derive a correction for the interpretation of the inspecting data of circuit pattern 52.

In addition to a simple shift, other kind of errors may occur, e.g., magnification, perpendicularity, or rotation. In order to determine the positioning error associated with those contributions, it is necessary to measure all four reference patterns 20. In addition, the measurement is performed for each reference pattern 20 in at least two perpendicular directions in order to derive a value in x- and y-direction.

As shown in FIG. 4, scanning of reference pattern 20 is performed in four different scanning windows, resulting in four measured distances: the first distance 62 is measured during scanning in window 60, a second distance is measured during scanning in second window 67, a third distance is measured during scanning in third window 69, and a fourth distance 62 is measured during scanning in fourth window 68. The first window 60 and third window 69 are parallel to each other and perpendicular to second window 67 and fourth window 68. The third direction is selected substantially parallel to the first axis at the third distance and at an opposite side with respect to the first direction. The fourth direction is selected substantially parallel to the axis at the fourth distance and at an opposite side with respect to the second direction.

Similarly, as described in FIG. 5, a second intensity profile 32, a third intensity profile 30′ and a fourth intensity profile 32′ are determined for each pattern 20.

As a result, a error vector is calculated from each nominal position for each reference pattern 20 using the first intensity profile 30, the second intensity profile 32, the third intensity profile 30′, and the fourth intensity profile 32′.

In a further step, a simulation model is provided. The simulation model has parameters capable of describing positioning errors induced by beam shifts, beam rotation, perpendicularity of the beam, and magnification errors. The parameters of the simulation model are determined from the error vectors for each reference position.

In this following example, X1 represents the offset in x-direction, e.g., derived from first intensity profile 30 and third intensity profile 30′ for the first reference pattern 20, e.g., the reference pattern in the upper left corner of frame 50. Similar, Y1 represents the offset in y-direction, e.g., derived from second intensity profile 32 and fourth intensity profile 32′ for the first reference pattern 20.

The error vector is given by X1 and Y1. For the simulation model, the following equation of the positioning error E₁₃ X and E₁₃ Y can be used:
E₁₃ X=X₁₃ Shift+Magnification*X*Rotation*Y, and
E₁₃ Y=Y₁₃ Shift+Magnification*Y*Rotation*X.

Using the error vectors for the four reference patterns 20, the parameter X₁₃ Shift, Y₁₃ Shift, Magnification, and Rotation are determined, using a standard algorithm to minimize the positioning error E₁₃ X and E₁₃ Y. This calculation is similar to the calculation performed in overlay metrology.

The foregoing embodiments described embodiments of the invention which used only one scanning electron microscope. The measurements are performed on a single substrate 2. The respective nominal positions of reference patterns 20 are derived from, e.g., a layout tool. The layout provides data for producing the substrate 2 including the reference patterns 20 and circuit pattern 52.

In high volume production lines, there are usually many different scanning electron microscopes 10 that provide measurement tools for inspecting a plurality of wafers or substrates 2.

According to a further embodiment, the inventive method can be used to determine not only the positioning error of a single scanning electron microscope 10, but also the tool matching between different scanning electron microscopes 10 by deriving the respective nominal positions from reference wafer and a reference scanning electron microscope.

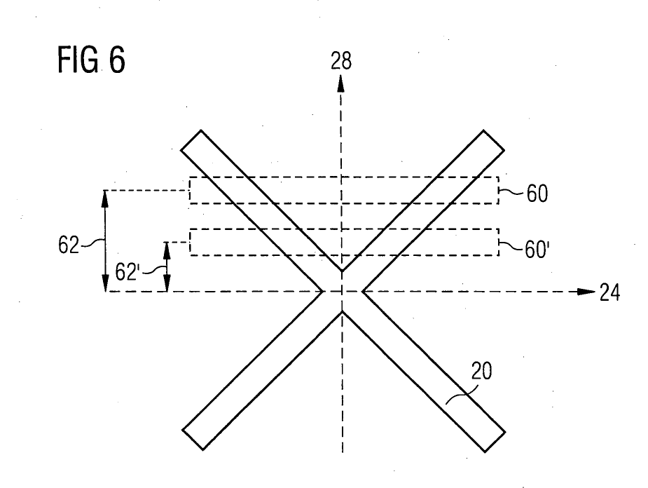

As shown in FIG. 6, an offset between different scanning electron microscopes results in different error vectors as well derived from, e.g., different first distances 62, 62′ in different scanning windows 60, 60′. This error vector is used to determine the parameters of the simulation model, similar as described with respect to FIGS. 4 and 5.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

List of reference numerals:

substrate 2
surface 4
scanning electron microscope 10
wafer stage 12
electron source 14
detector 16
substrate 20
electron beam 18
reference patterns 20
first dimension 22
first axis 24
second dimension 26
second axis 28
first intensity profile 30
second intensity profile 32
third intensity profile 30′
fourth intensity profile 32′
first direction 40
rectangular frame 50
circuit pattern 52
plurality of structural elements 54
first scanning window 60
first distance 62
second window 67
fourth window 68
third window 69

What is claimed is:

1. A method for determining a positioning error of an electron beam of a scanning electron microscope, comprising:
providing a substrate having at least four reference patterns at respective nominal positions on a surface of the substrate, each reference pattern having a continuously increasing first dimension along a first axis and a continuously increasing second dimension along a second axis, the first axis being different from the second axis;
providing a scanning electron microscope, the scanning electron microscope including a wafer stage, an electron source, and a detector;
positioning the wafer stage at respective nominal positions of each reference pattern;
scanning each reference pattern using an electron beam emitted from the electron source and using the detector to determine an intensity distribution of scattered electrons within a scanning window of the electron source;
determining at least a first intensity profile and a second intensity profile for each pattern, the first intensity profile being measured along a first direction and the second intensity profile along a second direction;
calculating a reference position offset from each nominal position for each reference pattern using at least the first intensity profile and the second intensity profile; and
determining a positioning error of the scanning electron microscope using the reference position offsets of each reference pattern.

2. The method according to claim 1, wherein providing a substrate includes providing the substrate with a circuit pattern arranged within a rectangular frame and that each reference pattern is arranged in a respective corner of the rectangular frame.

3. The method according to claim 1, wherein providing a substrate further includes that each reference pattern is arranged symmetrically with respect to the first axis and with respect to the second axis.

4. The method according to claim 3, wherein providing a substrate includes that the first axis and the second axis are substantially perpendicular to each other.

5. The method according to claim 4, wherein determining at least the first intensity profile and the second intensity profile for each of the patterns includes
selecting the first direction substantially parallel to the first axis at a first distance; and
selecting the second direction substantially parallel to the second axis at a second distance.

6. The method according to claim 5, wherein determining at least the first intensity profile and the second intensity profile for each pattern further includes
determining at least a third intensity profile and a fourth intensity profile for each pattern, the third intensity profile being measured along a third direction and the fourth intensity profile being measured along a fourth direction.

7. The method according to claim 6, wherein determining at least a third intensity profile and a fourth intensity profile for each pattern further includes
selecting the third direction substantially parallel to the first axis at a third distance and at an opposite side with respect to the first direction; and
selecting the fourth direction substantially parallel to the second axis at a fourth distance and at an opposite side with respect to the second direction.

8. The method according to claim 1, wherein calculating a reference position for each reference pattern includes
determining error vectors for each reference position, the error vector being calculated from the difference of the respective nominal position to the first distance, the second distance, the third distance, and the fourth distance.

9. The method according to claim 8, further comprising:
providing a simulation model of the scanning electron microscope, the simulation model having parameters capable of describing positioning errors induced by beam shifts, beam rotation, perpendicularity of the beam, and magnification errors; and
determining the parameters from the error vectors for each reference position.

10. The method according to claim 4, wherein providing the substrate further includes
providing each reference pattern as first and second straight bars, the bars being perpendicular to each other and under an angle of 45° with respect to the first axis and the second axis.

11. The method according to claim 8, wherein providing the substrate further includes
providing each reference pattern as first and second straight bars, the bars being perpendicular to each other and under an angle of 45° with respect to the first axis and the second axis.

12. The method according to claim 1, wherein providing the substrate further includes
providing a plurality of structural elements, the structural elements having a minimal size and representing a layer of an integrated circuit.

13. The method according to claim 12, wherein aligning the wafer stage and positioning the scanning window is performed using an optical microscope with an accuracy larger than the minimal size of the structural elements.

14. The method according to claim 12, wherein aligning the wafer stage and positioning the scanning window is performed using the scanning electron microscope with an accuracy larger than the minimal size of the structural elements.

15. The method according to claim 9, further comprising:
providing a measurement recipe for the scanning electron microscope to measure features of the structural elements;
modifying the recipe accounting for positioning errors described by the simulation model; and
measuring the features of the structural elements.

16. The method according to claim 10, further comprising:
providing a measurement recipe for the scanning electron microscope to measure features of the structural elements;
modifying the recipe accounting for positioning errors described by the simulation model; and
measuring the features of the structural elements.

17. The method according to claim 11, further comprising:
providing a measurement recipe for the scanning electron microscope to measure features of the structural elements;
modifying the recipe accounting for positioning errors described by the simulation model; and
measuring the features of the structural elements.

18. The method according to claim 12, further comprising:
providing a measurement recipe for the scanning electron microscope to measure features of the structural elements;
modifying the recipe accounting for positioning errors described by the simulation model; and
measuring the features of the structural elements.

19. The method according to claim 1, wherein the respective nominal positions are derived from a layout tool, the layout providing data for producing the substrate having the pattern.

20. The method according to claim 1, wherein the respective nominal positions are derived from reference wafer and a reference scanning electron microscope.

21. A system for measuring patterns with a scanning electron microscope, comprising:
a substrate having at least four reference patterns at respective nominal positions on a surface of the substrate, each of the reference patterns having a continuously increasing first dimension along a first axis and a continuously increasing second dimension along a second axis, the first axis being different from the second axis;
a scanning electron microscope, the scanning electron microscope including a wafer stage, an electron source, and a detector;
means for positioning the wafer stage at respective nominal positions of each reference pattern;
means for scanning each reference pattern using an electron beam emitted from the electron source and using the detector to determine an intensity distribution of scattered electrons within a scanning window of the electron source;
means for determining at least a first intensity profile and a second intensity profile for each of the patterns, the first intensity profile being measured along a first direction and the second intensity profile being measured along a second direction;
means for calculating a reference position offset from each nominal position for each reference pattern using at least the first intensity profile and the second intensity profile; and
means for determining a positioning error of the scanning electron microscope using the reference position offsets of each reference pattern.

22. A system for measuring patterns with a scanning electron microscope, comprising:
a substrate having at least four reference patterns at respective nominal positions on a surface of the substrate, each of the reference patterns having a continuously increasing first dimension along a first axis and a continuously increasing second dimension along a second axis, the first axis being different from the second axis;
a scanning electron microscope, the scanning electron microscope including a wafer stage, an electron source, and a detector;
a wafer position module for positioning the wafer stage at respective nominal positions of each reference pattern;
a scanner for scanning each reference pattern using an electron beam emitted from the electron source and using the detector to determine an intensity distribution of scattered electrons within a scanning window of the electron source;
an intensity profile module for determining at least a first intensity profile and a second intensity profile for each of the patterns, the first intensity profile being measured along a first direction and the second intensity profile being measured along a second direction;
a calculator for calculating a reference position offset from each nominal position for each reference pattern using at least the first intensity profile and the second intensity profile; and
a position error module for determining a positioning error of the scanning electron microscope using the reference position offsets of each reference pattern.
